(19) United States
(12) Patent Application Publication
(10) Pub. No.: US 2006/0171117 A1
(43) Pub. Date: Aug. 3, 2006

(54) Cooling system

(75) Inventor: Brian A. Hamman, Krugerville, TX (US)

Correspondence Address: Arthur W. Fisher;Patent Dominion LP, Suite 200, 555 Republic Drive, Plano, TX, 75074, US

(73) Assignee: QNX Cooling Systems, Inc.

(21) Appl. No.: 11/361,943

(22) Filed: Feb. 27, 2006

Related U.S. Application Data
(63) Continuation-in-part of application No. 10/964,344, filed on Oct. 13, 2004.

(51) Int. Cl. H05K 7/20

(52) U.S. Cl. 361/699

(57) ABSTRACT

A cooling system with quick connectors is presented. A number of embodiments are presented. The cooling system includes one or more heat transfer units disposed on one or more circuit cards and thermally coupled to one or more heat generating components. As the circuit cards are inserted into or disconnected from an electronic system, coolant communication is enabled or disabled, respectively between one or more heat exchange units and the heat transfer units disposed on the circuit card at the time electrical connection of the circuit card is established or disconnected, respectively.

### CROSS REFERENCE TO RELATED APPLICATIONS

This application is a continuation-in-part of pending U.S. patent application Ser. No. 10/964,344 filed Oct. 13, 2004. Reference is made to pending U.S. patent application Ser. No. 10/688,587 filed Oct. 18, 2003 for a detailed description of cooling systems and various heat transfer units and heat exchangers and their operation. Reference is also made to pending U.S. patent application Ser. No. 11/319,942 filed Dec. 29, 2005 for a detailed description of connector heat transfer units and to pending U.S. patent application Ser. No. 11/336,304 filed Jan. 23, 2006 for a detailed description of leakage or spillage sensors.

### BACKGROUND OF THE INVENTION

### Description of the Related Art

At the heart of data processing and telecommunication devices are processors and other heat-generating components which are becoming increasingly more powerful and generating increasing amounts of heat. As a result, more powerful cooling systems are required to prevent these components from thermal overload and resulting system malfunctions or slowdowns.

Traditional cooling approaches such as heat sinks and heat pipes are unable to practically keep up with this growing heat problem. As these components become increasingly more powerful, the size and weight of air-cooled solutions become more problematic as well. In smaller housings or rack mounted systems, the space required for air-cooled solutions becomes unacceptable. Cooling systems which use a liquid or gas to cool these heat generating components are becoming increasingly needed and more viable. These systems utilize heat transfer units thermally coupled to the heat generating components for absorbing or extracting heat from the heat generating components into a coolant flowing there through. The coolant, now heated, is directed to a heat exchanger where heat is dissipated from the coolant, creating cooled coolant and returned to the heat transfer unit to repeat the cycle.

Liquid cooling for these heat generating components is a more viable approach to this heat problem. A typical liquid cooling system employs one or more heat transfer units thermally coupled to the heat generating components for absorbing heat from the components into the liquid coolant and a heat exchanger which dissipates heat from the coolant and returns cooled liquid to the heat transfer units.

The heat transfer typically comprises of a housing with a cavity there through for the coolant to flow through. The contact surface (with the heat generating components) must have excellent thermal transfer capability and a wide variety of materials can be used such as copper.

Many of the heat generating components of today and high powered microprocessors, in particular, are connected into the electronic system in which they will be used by means of a socket or connector. The socket is often soldered into a motherboard and has receptacles for receiving the pins of the component and allows for easy insertion and extraction into and out of the motherboard. The component then is not subjected to any mishaps that may incur during soldering or whatever insertion method is used.

For today's powerful microprocessors, for example, a bulky, heavy air cooled solution such as a heat sink or heat pipe dissipater must then be coupled to heat generating component and to the motherboard for fastening which often causes problems such as breakage of the motherboard from the substantial forces that must be generated to secure the entire assembly and even shipping damage from inertia due to the heavy weight of the air cooled cooling devices.

The cost and complexity of final assembly of motherboards and systems with these large, air cooled solutions also becomes problematic with space problems and expensive, and often damaging, processes for securing the air cooled system to the heat generating component and to the motherboard.

Thus, there is a need in the art for a method and apparatus for space-efficient, cost-efficient cooling systems which provide powerful cooling of the components.

### SUMMARY OF THE INVENTION

A method and apparatus for cooling heat generating components in an electronic system having one or more heat exchange units for receiving heated coolant and cooling said coolant; one or more heat transfer units disposed on one or more boards or circuit cards and thermally coupled to one or more heat generating components, the heat transfer units receiving cooled coolant from a heat exchange unit, heating the coolant by transferring heat from the heat generating components thereto and directing the heated coolant to a heat exchange unit for cooling; an interconnect system for enabling and disabling coolant communication between the heat exchange units and the heat transfer units; and a coolant transport system coupled to the interconnect system and the heat exchange units and heat transfer units for transporting coolant between the heat exchange units and the heat transfer units, the coolant transport system disposed within the electronic system such that the connection of circuit cards to the electronic system engages the interconnect system enabling coolant communication between the heat transfer units disposed on such circuit card and one or more heat exchange units and disconnecting the circuit card from the electronic system disengages the interconnect system disabling coolant communication between the heat transfer units disposed on such circuit card and the heat exchange units.

A method and apparatus for cooling heat generating components in an electronic system as described above wherein at least one heat exchange unit is disposed within the housing of the electronic system.

A method and apparatus for cooling heat generating components in an electronic system as described above wherein the interconnect system comprises one or more quick connectors having an insert and a receptacle and disposed such that one or more inserts and receptacles engage when a circuit card is connected to the electronic system enabling coolant communication and disconnect when a circuit card is disconnected from the electronic system, disabling coolant communication.

A method and apparatus for cooling heat generating components in an electronic system as described above wherein the quick connectors establish a seal before enabling or disabling coolant communication to minimize leakage of coolant when the quick connectors are being connected or disconnected, respectively.

A method and apparatus for cooling heat generating components in an electronic system as described above wherein the coolant transport system includes one or more heat transfer unit coolant transportation means disposed on one or more of the circuit cards and coupled to the inlets and outlets of the heat transfer units and coupled to one or more inserts or receptacles of the quick connectors such that such inserts or receptacles engage with their mating receptacles or inserts, respectively, of the quick connectors when the circuit card is connected to the electronic system.

A method and apparatus for cooling heat generating components in an electronic system as described above wherein one or more of the inserts or receptacles of the quick connectors coupled to the heat transfer unit transportation means forms a seal when not engaged with its mating receptacle or insert, respectively, enabling such transportation means to contain coolant such that the cooling system has the appropriate volume of coolant at all times, irrespective of the number of circuit cards connected to the electronic system and minimizing the leakage or spillage of coolant from such transportation means.

A method and apparatus for cooling heat generating components in an electronic system as described above wherein the coolant transport system includes heat exchange unit coolant transportation means coupled to the inlets and outlets of one or more heat exchange units and coupled to one or more inserts or receptacles of the quick connector such that such inserts or receptacles engage with their mating receptacle or insert, respectively, of the quick connectors when a circuit card is connected to the electronic system.

A method and apparatus for cooling heat generating components in an electronic system as described above wherein one or more of the inserts or receptacles of the quick connectors coupled to the heat exchange unit transportation means forms a seal when not engaged with its mating receptacle or insert, respectively, thereby minimizing the leakage or spillage of coolant.

A method and apparatus for cooling heat generating components in an electronic system as described above wherein the transport system and interconnect system are disposed in the electronic system and on one or more of the circuits cards such that a secure mechanical connection of such circuit cards to the electronic system is maintained when the circuit cards are connected to the electronic system.

A method and apparatus for cooling heat generating components in an electronic system as described above further including a collection means disposed in proximity to the interconnect system for collecting coolant spilled or leaked from the interconnect system and directing such spilled or leaked coolant back to the cooling system.

A method and apparatus for cooling heat generating components in an electronic system as described above further including a sensing means disposed within the collection means for detecting the presence of coolant in the collection means and providing a notification to the electronic system user or operator there of.

A method and apparatus for cooling heat generating components in an electronic system as described above wherein the inlets of one or more heat transfer units are disposed below the outlets of such heat transfer units enhancing convective circulation of the coolant.

A method and apparatus for cooling heat generating components in an electronic system as described above wherein the inlets of one or more heat exchange units are disposed above the outlets of such heat exchange units enhancing convective circulation of the coolant.

A method and apparatus for cooling heat generating components in an electronic system as described above wherein the electronic system includes one or more sliding guides for connecting and disconnecting the printed circuit cards from the electronic system.

A method and apparatus for cooling heat generating components in an electronic system as described above wherein one or more of the heat transfer units is a socket heat transfer unit, the socket heat transfer unit including a housing having one or more first cavities thermally coupled to one or more heat-generating components, wherein a coolant flowing through the cavities absorbs heat from the heat-generating components creating heated coolant; means for electrically coupling electrical conductors of the heat-generating components to the electronic system; one or more inlets for receiving coolant and directing the coolant through the cavities; and one or more outlets for receiving heated coolant from the cavities and directing the heated coolant out of the socket heat transfer unit.

A quick connector for establishing coolant communications in a cooling system for cooling heat-generating components in an electronic system including; one more inserts; one or more receptacles for engaging with the inserts; and first sealing means within the inserts and receptacles for sealing the inserts and connectors when such inserts and receptacles are not engaged and for unsealing the inserts and receptacles when such inserts and receptacles are engaged, thereby enabling coolant communication there through.

The quick connector as described above and having a second sealing means for creating a seal between an insert and receptacle prior to engagement of the insert with the receptacle and the unsealing of the first sealing means and the enabling of coolant communication and maintaining such seal between the insert and receptacle during disengagement of the insert from the receptacle until after the first sealing means has re-sealed, said second sealing means minimizing the coolant spilled or leaked during engagement and disengagement of the insert and the receptacle.

The quick connector as described above and having a housing coupled to one or more receptacles and through which one or more of the inserts engages the one or more of the receptacles, the housing having -means for collecting coolant spilled or leaked from the quick connector and for directing such spilled or leaked coolant to a coolant source.

The quick connector as described above having one or more sensors disposed in the housings for sensing the presence of coolant in the housing.

The quick connector as described above having one or more detectors responsive to sensors for providing an indication to the user or operator of the system of the presence of coolant in the housing.

The quick connector as described above wherein the means for collecting spilled or leaked coolant further includes means for forcing such spilled or leaked coolant to the coolant source.

### BRIEF DESCRIPTION OF THE DRAWINGS

FIG. 1A depicts a motherboard with a heat transfer unit and conduits for transporting coolant to and from the heat transfer unit.

FIG. 1B depicts a system housing with a heat exchange unit and conduits for transporting coolant to and from the heat exchange unit.

FIG. 1C depicts a motherboard with a heat transfer unit connected to the system housing with the heat exchange unit and conduits for transporting coolant between the heat exchange unit and the heat transfer unit.

FIG. 2A depicts a motherboard with an electrical connector and with a heat transfer unit and conduits for transporting coolant to and from the heat transfer unit, the conduits being affixed to the motherboard and terminated with an insert of a quick connector.

FIG. 2B depicts a system housing with slide guides and a electrical connector for a motherboard and with a heat exchange unit and conduits for transporting coolant to and from the heat exchange unit, the conduits being terminated with an insert of a quick connector disposed to accept the receptacles of the mating quick connector from the motherboard when the motherboard is inserted into the system housing.

FIG. 2C depicts the motherboard of FIG. 2A and the system housing of FIG. 2B connected together.

FIG. 3 is a cross-sectional view of a server system housing with slide guides and an electrical connector for a motherboard and with a heat exchange unit and conduits for transporting coolant to and from the heat exchange unit, the conduits being terminated with receptacles of a quick connectors disposed to accept the mating inserts of the quick connectors from the motherboard when the motherboard is inserted into the system housing. A spill drain is also depicted. FIG. 3 also depicts a circuit card for a server with an electrical connector and with a heat transfer unit and conduits for transporting coolant to and from the heat transfer unit, the conduits being affixed to the circuit card and terminated with an insert of a quick connector.

FIG. 4 depicts a schematic view of a quick connector with apparatus for catching spilled or leaked coolant.

FIG. 5A depicts a detailed, cross-sectional view of a quick connector disengaged.

FIG. 5B depicts a detailed, cross-sectional view of a quick connector partially engaged or disengaged.

FIG. 5C depicts a detailed, cross-sectional view of a quick connector engaged.

### DETAILED DESCRIPTION

Whilst the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention and do not limit the scope of the invention.

It should be understood that the principles and applications disclosed herein can be applied in a wide range of data processing systems, telecommunication systems and other systems such as electrical and electronic systems. In the present invention, heat produced by a heat generating component, such as, but not limited to, a microprocessor in a data processing system, is transferred to a coolant in a heat transfer unit and dissipated in the cooling system. Liquid cooling solves performance and reliability problems associated with heating of various heat generating components in electronic systems.

The present invention may be utilized in a number of computing, communications, and personal convenience applications. For example, the present invention could be implemented in a variety of servers, workstations, exchanges, networks, controllers, digital switches, routers, personal computers which are portable or stationary, cell phones, and personal digital assistants (PDAs) and many others.

The present invention is equally applicable to a number of heat-generating components (e.g., central processing units, optical devices, data storage devices, digital signal processors or any component that generates significant heat in operation) within such systems. Furthermore, the dissipation of heat in this cooling system may be accomplished in any number of ways by a heat exchange unit of various designs, but which are not discussed in detail in this application. The present invention may even be combined with a heat exchanger as part of a single unit to constitute the entire cooling system.

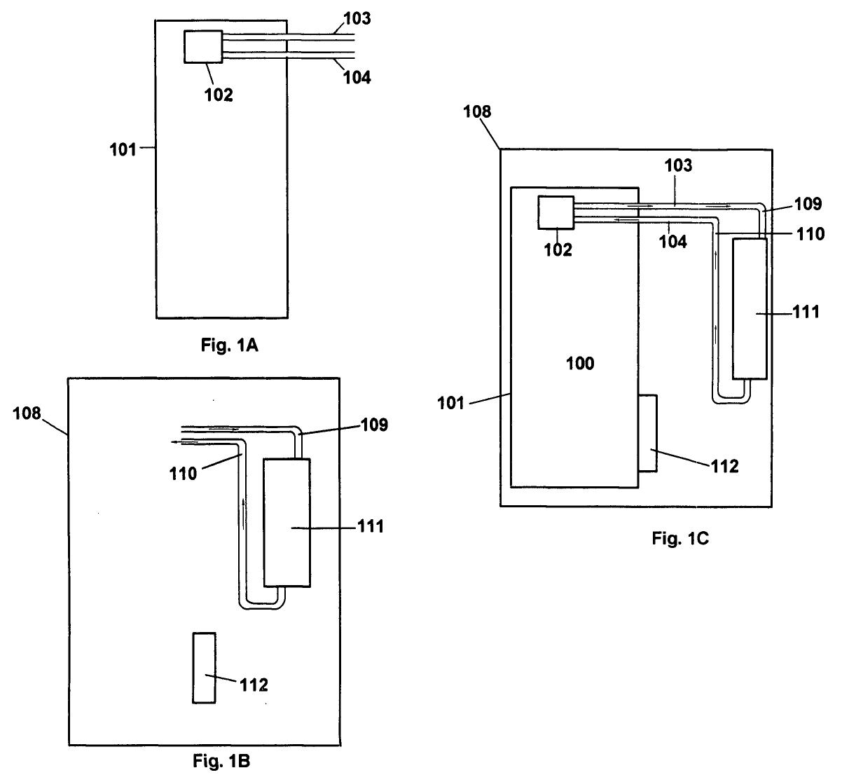

Referring now to FIGS. 1A, 1B and 1C, a motherboard 101, a system casing 108 and a combination of the motherboard 101 connected to an electronic system in the casing 108 are depicted.

In FIG. 1A, the motherboard 101 is shown as a circuit board or card populated with numerous components (not shown). A heat transfer unit 102 is shown disposed on the motherboard 101. The heat transfer unit is thermally coupled to one or more heat generating components, such as, but not limited to, a microprocessor, on the motherboard 101. The heat transfer unit 102 receives cooled coolant through conduit 104. As the cooled coolant circulates through the heat transfer unit 102, heat is absorbed into the coolant from the heat generating components, cooling the heat generating components and creating heated coolant. The heated coolant is then directed out of the heat transfer unit 102 and into conduit 103 to be cooled by the heat exchange unit and returned to the heat transfer unit 102 via conduit 104.

It will be appreciated that all of the embodiments of the present invention encompasses the use of any form or type of heat transfer unit or the combination of different types of heat transfer units. However, a connector or socket heat transfer unit as described in U.S. patent application Ser. No. 11/319,942 filed Dec. 29, 2005 is preferable. This form of heat transfer unit can be used with one or more heat generating components and can be soldered or otherwise affixed to the motherboard 101 before the heat generating components are inserted. It further provides the advantage of easy assembly due to automatic coupling of conduits 103 and 104 when the circuit board or motherboard 101 is inserted into the system housing.

In FIG. 1B, a partial view of a casing or housing 108 for the electronic system is depicted with a heat exchange unit 111 coupled thereto. Heated coolant from the heat transfer unit 102 enters the heat exchange unit 111 through conduit 109. Heat is dissipated from the coolant by the heat exchange unit 111 and cooled coolant is transported back to the heat transfer unit 102 through conduit 110. An electrical receptacle 112 is also depicted which electrically connects to a connector (not shown) on the motherboard 101 for electrically connecting the motherboard 101 to the electronic system.

It will be understood that, in all of the embodiments of the present invention, any number and type of heat exchange units may be employed in any of the embodiments of the present invention including heat exchange units with or without reservoirs; with or without a pump; and with or without fans or other air flow devices. It should also be appreciated that a remotely mounted or external heat exchange unit may also be used. The heat exchange unit 111 may be used to cool one or more heat transfer units 102 connected in series or parallel or any combination thereof.

Any number of coolants, liquid or gas, may be used with any of embodiments of the present invention such as, for example, a propylene-glycol based coolant. The scope of this invention also includes refrigerated cooling systems of all types including, but not limited to, systems utilizing both conventional Freon and chilled coolant systems. This refrigerated cooling embodiment would include, for example, a heat exchange unit including a heat exchanger, a compressor, and an expansion valve or other flow control device, either in a single piece of equipment or as separate components, in conjunction with the heat transfer units herein to cool the heat generating components thermally coupled to the heat transfer units. Solid state refrigeration may also be utilized.

In FIG. 1C, the motherboard 101 is depicted connected to the casing or housing 108. The cooling system 100 comprises heat transfer unit 102, heat exchange unit 111 and conduits 103, 104, 109 and 110. The connection of conduits 103 to 109 and conduits 104 to 110 may take place anywhere in the electronic system of convenience for assembly in the system and is preferably in the form of quick connectors which provide for rapid and cost-efficient assembly of the system. The conduits may remain as loose assemblies or may be coupled in harnesses. Additionally, they may be fastened to the motherboard 101 and/or the casing or housing 108 or they may be free-standing.

Whenever possible, it is desirable to orient the heat transfer unit 102 as shown in FIGS. 1A and 1C and all of the embodiments of the present invention so that cooled coolant is received at a point below where heated coolant exits the heat transfer unit 102. This orientation allows the cooling system to take advantage of convective circulation of the coolant since heated coolant will naturally rise and cooled coolant will naturally drop. In this manner, the thermodynamics of the coolant can assist forced circulation, by a pump for example, and provide additional cooling of the heat generating components even after power is shut down to the electronic system through convective circulation. Similarly, and for the same reasons, it is desirable to orient the heat exchange unit 111 as shown in FIGS. 1B and 1C and any of the embodiments of the present invention so that heated coolant is received at a point above where cooled coolant exits the heat exchange unit 111.

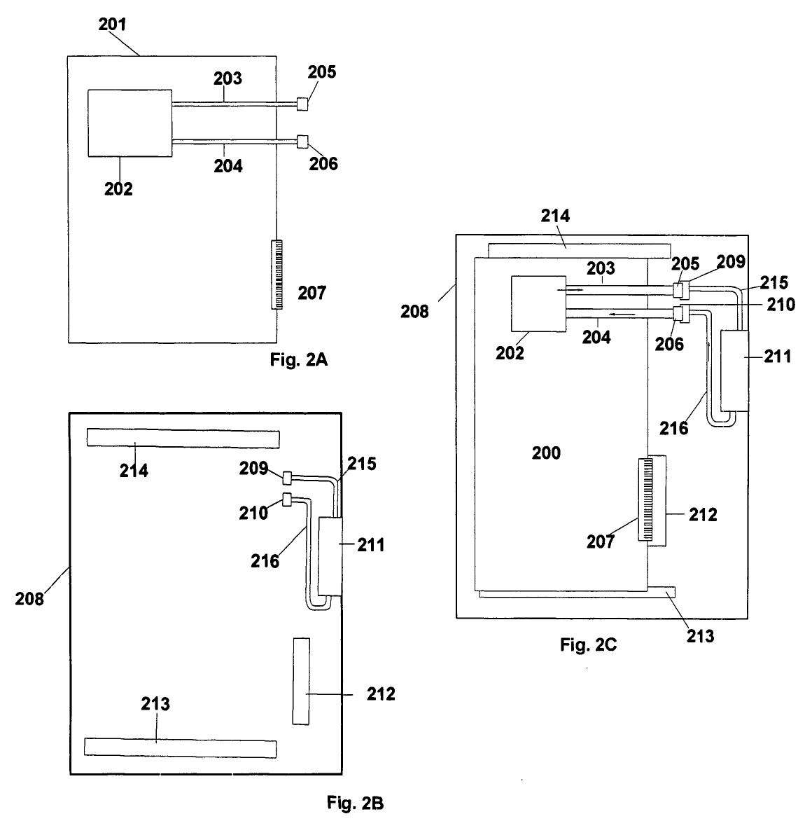

In FIGS. 2A, 2B and 2C, another embodiment of the present invention is depicted. In FIG. 2A, a motherboard or printed circuit card 201 is depicted. The motherboard 201 is populated with components, not shown. An electrical connector 207 is disposed on an edge of the motherboard for enabling electrical connection of the motherboard to the electronic system when inserted into receptacle 212. A heat transfer unit 202 is disposed on the motherboard and thermally coupled to one or more heat generating components such as microprocessors. Cooled coolant is received by the heat transfer unit through conduit 204. The coolant is heated in the heat transfer unit 202 by the transfer of heat from the heat generating components to the coolant and the heated coolant exits the heat transfer unit 202 through conduit 203.

Conduits 203 and 204 are terminated with a quick connector inserts 205 and 206, respectively.. Conduits 203 and 204 are coupled to the motherboard 201 such that their positioning remains fixed and so that, when the motherboard 201 is inserted into the electronic system, the quick connector inserts 205 and 206 automatically align with and connect to their corresponding receptacles, 209 and 210, respectively, of the quick connectors.

The inserts 205 and 206 may include an automatic sealing mechanism such that, when not connected to their mating receptacles, 209 and 210, respectively, a seal is formed preventing any coolant from escaping from the heat transfer unit 202 or conduits 203 and 204. Use of such a sealing mechanism allows for the disposition of coolant in the heat transfer unit 202 and conduits 203 and 204 before connection to the rest of the cooling system 200. It also prevents excessive leaks or spills of coolant when a motherboard is disconnected from the electronic system. Additionally, use of such sealing mechanisms insures the correct volume of coolant will be available for the cooling system 200 at all times which is particularly important when a reservoirless heat exchange unit is used or a plurality of motherboards with heat transfer units are to be used in the electronic system.

It will be understood that motherboard 201 may have more than one heat transfers units 202 disposed thereon and connected in similar fashion.

In FIG. 2B, a partial view of a casing or housing 208 for the electronic system is depicted with a heat exchange unit 211 coupled thereto. Heated coolant from the heat transfer unit 202 enters the heat exchange unit 211 through receptacle 209 and conduit 215. Heat is dissipated from the coolant by the heat exchange unit 211 and cooled coolant is provided for transfer back to the heat transfer unit 202 through conduit 216 and receptacle 210.

Receptacles 209 and 210 mate with inserts, 205 and 206, respectively, and form quick connectors 205/209 and 206/210. Receptacles 209 and 210 are disposed and secured in the casing or housing 201 such that their positioning remains fixed and so that, when the motherboard 201 is inserted into the electronic system, the quick connector receptacles 209 and 210 automatically align with and connect to their corresponding inserts, 205 and 206, respectively. Conduits 215 and 216 are preferably part of a harness which is affixed at various places to the housing or casing 208. It will be understood though, that other methods of deploying the conduits 215 and 216, such as leaving them free-standing or not using a harness, are within the scope of the present invention.

The receptacles 209 and 210 may include an automatic sealing mechanism such that, when not connected to their mating connectors, 205 and 206, respectively, a seal is formed preventing any coolant from escaping from the heat exchange unit 211 or the cooling system 200. Use of such a sealing mechanism allows for the disposition of coolant in the heat exchange unit 211 before connection to the rest of the cooling system 200. It also prevents excessive leaks or spills of coolant when the circuit card or motherboard 201 is disconnected from the electronic system. Additionally, use of such sealing mechanisms insures that the correct volume of coolant will always be available for the cooling system 200 which is particularly important when a reservoirless heat exchange unit 211 is used or a plurality of motherboards with heat transfer units are to be used in the electronic system.

The casing or housing also includes a means to guide the circuit board such as, but not limited to, a pair of slide guides 213 and 214 and an electrical receptacle 212 for mating with connector 207 when the motherboard 201 is inserted into the casing or housing 208 and establishing electrical connection of the motherboard 201 to the electronic system. The slide guides 213 and 214 are secured and disposed within the casing or housing 208 so that the motherboard 201 can be inserted therein and then be guided into the housing or casing 208. Electrical connection is automatically established between connector 207 and receptacle 212 and coolant communications is automatically established between the heat exchanger 211 and -the heat transfer unit 202.

In FIG. 2C, the motherboard 201 is depicted connected to the casing or housing 208, the motherboard 201 having been inserted into the slide guides 213 and 214 such that connector 207 has mated with receptacle 212, electrically connecting the motherboard 201 to the electronic system, and inserts 205 and 206 having mated with receptacles 209 and 210, respectively, establishing coolant communication between the heat exchange unit 211 and the heat transfer unit 202. The cooling system 200 comprises heat transfer unit 202, heat exchange unit 211 and conduits 203, 204, 215 and 216 and quick connectors 205/209 and 206/210. The securing and alignment of quick connectors 205/209 and 206/210 coupled with the use of guide slides 213 and 214 provide for extremely fast and cost efficient assembly and connection of the cooling system 200. Moreover, the secure mating of quick connectors 205/209 and 206/210 provide additional securing of the entire motherboard 201 to the electronic system and decrease the need for other mechanisms such as clips to secure the motherboard 201 in place.

It will be appreciated then that the present invention permits a motherboard or circuit card 201 to be inserted or removed seamlessly from an electronic system while the electronic system is operating and while the cooling system 200 is operating and without any need to shut the systems down or special installation requirements.

It will be further understood that, in all embodiments of the present invention, the quick connectors may also be arranged so that the insert portions are disposed in the housing or casing 208 and the receptacle portions are coupled to conduits 203 and 204. Additionally, other combinations may be used such as, for example, a insert coupled to conduit 203 and receptacle coupled to conduit 204 and the mating portions disposed in the housing or casing 208.

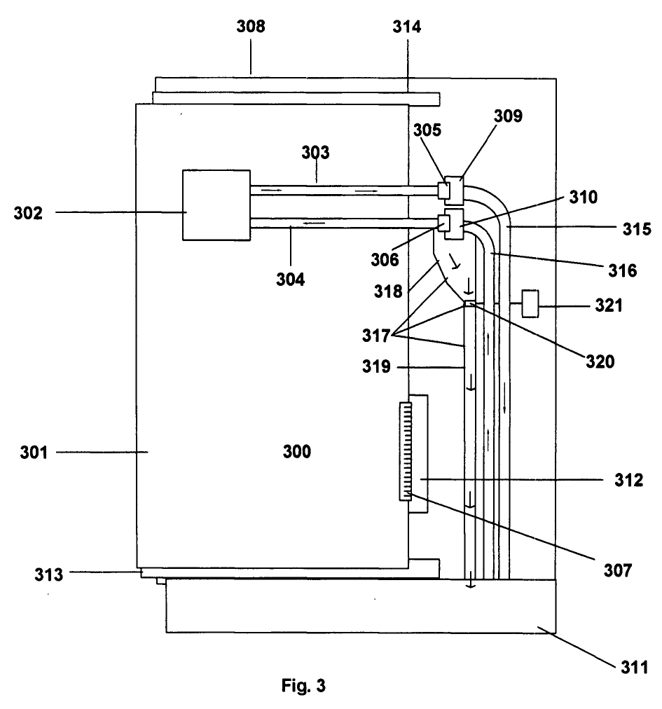

Referring now to FIG. 3, a cross sectional view of one of a plurality of motherboards or circuit cards 301 inserted into a housing or casing 308 for a system such as a server. The server system is designed for rack mounting, such that a number of circuit cards can be inserted into the housing or casing 308 and connected to the server system while in operation. Typically, the circuit cards are disposed adjacent and parallel to each other in the system.

In FIG. 3, a circuit card 301 is shown. An electrical connector 307 is affixed to the printed circuit card 301 for electrically connecting the circuit card 301 to the server system when connected/mated to receptacle 312. A heat transfer unit 302 is thermally coupled to one or more heat generating components (not shown). A conduit 303 is coupled to an outlet of the heat transfer unit 302 and terminates with a coupling to an insert 305 of a quick connector. A conduit 304 is coupled to an inlet of the heat transfer unit 302 and terminates with a coupling to an insert 306 of a quick connector. Both conduits 303 and 304 are securely coupled to the circuit card 301 so that inserts 305 and 306 of the quick connectors are properly aligned to mate with and connect to the receptacles 309 and 310, respectively, of the quick connectors, when the circuit card is inserted into the server system housing or casing 308.

It will be understood that the heat transfer unit 302 may be any one of a variety of heat transfer units such as a connector or socket heat transfer unit and it may be thermally coupled to more than one heat generating component, such as, but not limited to, a microprocessor. Additionally, it will be understood that the circuit card may have more than one heat transfer unit coupled to conduits 303 and 304 or that there may be more than one conduit/insert assembly for the plurality of heat transfer units.

The server system housing or casing 308 has one or more guides such as slide guides 313 and 314 for easy insertion and alignment of the circuit card 301 into the housing or casing 308. When two or more circuit cards are to be inserted into the system, additional guides would be provided. Electrical receptacle 312 is also disposed in the casing 308 for mating with connector 307 and electrically connecting the circuit card 301 to the server system. Additional receptacles would be included for additional circuit cards to be inserted into the system.

Heat exchange unit 311 is mechanically coupled to the system housing or casing 308. The heat exchange unit 311 is depicted in FIG. 3 as disposed within the casing or housing 308. However, it will be understood that the heat exchange unit may be connected to the outside of the housing or casing 308 or even remotely disposed from the casing or housing 308 and still be within the ambit of the present invention. In FIG. 3, the heat exchange unit 311 is shown as a single unit. It will be understood that two or more, smaller heat exchange units may be utilized and disposed in different locations and remain within the purview of the present invention. As mentioned above, the heat exchange unit 311 may be any one of a variety of different types of heat exchangers.

Conduit 315 is coupled to an inlet of the heat exchange unit 311 and terminates with a coupling to a receptacle part 309 of a quick connector. Conduit 316 is coupled to an outlet of the heat exchange unit-311 and terminates with a coupling to a receptacle 310 of a quick connector. Both receptacles 309 and 310 are securely coupled to the housing or casing 308 so that they are properly aligned to mate with and connect to the inserts 305 and 306, respectively, of the quick connectors, when the circuit card is inserted into the server system housing or casing 308. The conduits 315 and 316 may be secured separately or as part of a harness to various points of the housing or casing 308 or they may be free standing. Additional conduits or harnesses and receptacles of quick connectors may be used for additional heat transfer units on a circuit card and/or additional circuit cards and/or additional heat exchange units.

The cooling system 300 as depicted in FIG. 3 comprises the heat transfer unit 302, conduits 303 and 304, quick connectors 305/309 and 306/310, conduits 315 and 316, and heat exchange unit 311. In operation, heated coolant is received at the inlet of the heat exchange unit 311. Heat is dissipated from the coolant by the heat exchanger 311 producing cooled coolant at an outlet of the heat exchange unit 311. The cooled coolant is transported via conduit 316, quick connector 306/310 and conduit 304 to an inlet of the heat transfer unit 302. As the coolant flows through the heat transfer unit 302, heat is transferred from the heat generating components to the coolant creating heated coolant. The heated coolant is transported from an outlet 302 of the heat transfer unit, via conduit 303, quick connector 305/309, and conduit 315 to the inlet of the heat exchange unit 311 where the process is repeated.

Since it is virtually impossible to prevent completely some leakage or spillage of coolant, particularly at the quick connectors 305/309 and 306/310 when the circuit cards are being inserted or removed from the electronic system, the cooling system 300 includes a coolant collector 317 to collect any leakage or spillage of coolant and return it to the heat exchange unit 311. The coolant collector 317 may encompass a variety of implementations such as an open trough 318 disposed underneath all quick connectors, such as 305/309 and 306/310 in the system and one or more conduits 319 for transporting the spilled or leaked coolant to the heat exchange unit 311. At or near the connection(s) of the trough to the conduit(s) 319, a leak or spill sensor 320 may be disposed. The sensor 320 can be of a variety of implementations, such as a wire mesh or grid which conducts a small amount of electricity when coolant passes through the sensor. The sensor may then be connected to a detector 321 which provides the system user/operator with an indication that coolant is present in the coolant collector 317. Although this indication is not necessarily needed when a circuit card 301 is being connected or disconnected, it will be highly advantageous in the event of a leak or spill at or near the quick-connect assemblies during normal operation. Moreover, each sensor used can be detected separately by a detector to provide the system user or operator with a more precise indication of the location of the spill or leak.

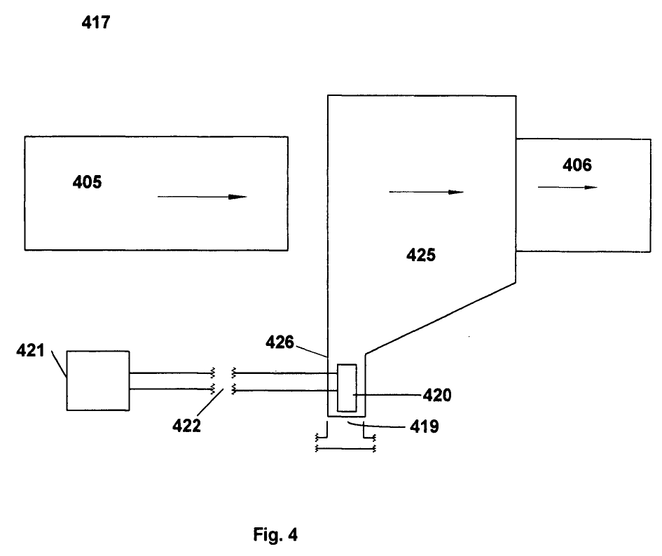

In FIG. 4, another embodiment of a coolant collector 417 is depicted. A housing coupling 425 is coupled to receptacle 406 of a quick connector. Insert 405 of the quick connector, when being mated with receptacle 406, is inserted into and through housing coupling 425 and into receptacle 406 establishing coolant flow. Any coolant leaked or spilled at the insert 405/receptical 406 connection of the quick connector is caught by housing coupling 425 and falls to the neck 426 of the housing coupling 425. The spilled or leaked coolant then passes through the neck 426 into a conduit 419 for return to a heat exchange unit (not shown in FIG. 4). Disposed in the-neck 426 of the housing coupling 425, is a sensor 420 which reacts to the presence of coolant in the neck 426. A detector 421 is coupled to the sensor 420 via conductors 422 and provides an indication to the system user or operator that coolant is present in the neck 426.

The sensor 420 may encompass any number of implementations such as, but not limited to, a conductive wire grid coupled to a power source so that, when coolant is present in the neck 426, an electric current flows through the grid and consequently through conductor assembly 422. Detector 421 detects the flow of current in conductor assembly 422 and provides the indication to the system user or operator.

In a system such as a server, housing coupling 425 may be a discrete component for each quick-connect assembly. In this embodiment, the system user or operator can easily be provided with an indication of the exact location of a coolant leak or spill in the system. Each neck 426 may be coupled to its own return conduit 419 or all necks 426 may be coupled to the same return conduit 419 or sets of necks may be coupled to a conduit 419. Alternatively, all necks 426 may be disposed over one or more open troughs, as depicted in FIG. 3, so that spilled or leaked coolant drops into the trough from the neck 426 and is circulated back to the heat exchanger (not shown) by means of one or more conduits 419.

Alternatively, housing coupling 425 may be an assembly which accepts a plurality of quick-connect assemblies. An advantage to this approach is the one coupling may be fabricated which is easy to install in a system such as a server and may be assembled quickly and easily with the receptacle portions of all or a plurality of the quick-connect assemblies with exact alignments to mate with connector portions of the quick-connect assemblies. In this alternative arrangement, the various implementations for the sensors 420 and the return conduit 419 arrangements previously described may also be employed. It should also be appreciated that the coolant inserts can have an enclosed housing as opposed to a simple trough. This enclosed housing for catching lost coolant in one embodiment can utilize a force, such as, but not limited to, a suction or pressure to scavenge lost coolant, and return the coolant to the cooling system.

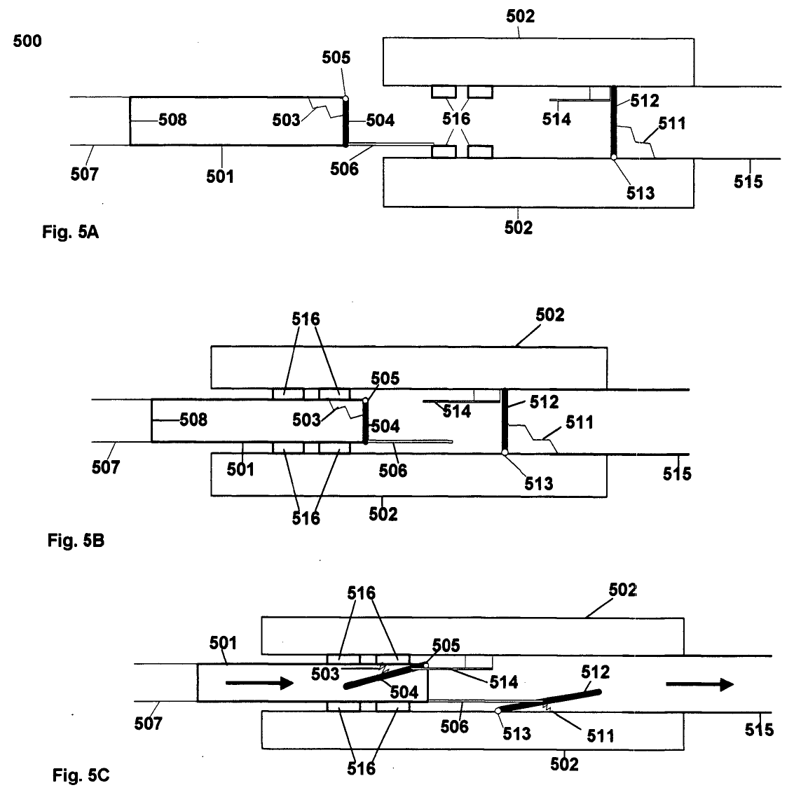

In FIG. 5A, a cross-sectional view of a quick connector 500 with an insert 501 and receptacle 502 disengaged. The insert 501 includes an insert gate spring 503 connected to the inner wall of the insert 501 and an insert coupler 504. The insert coupler 504 is held in the closed or sealed position by spring 503 and prevents the flow of coolant out of insert 501. The insert coupler 504 is movably connected to the inside of the insert 501 by a hinge 505 or any other such means which allows the coupler 504 to be opened when pressure, for example, is forced against the coupler 504 as when the insert 501 is connected to the receptacle 502. A receptacle coupler opener 506 is also depicted extending outwardly from the wall of insert 501 and a conduit 507 is depicted coupled to the insert 501 at 508.

The receptacle 502 includes a receptacle gate spring 511 connected to the inner wall if the receptacle 502 and a receptacle coupler 512. The receptacle coupler 512 is held in the closed or sealed position by spring 511 and prevents the flow of coolant out of receptacle 502. The receptacle coupler 512 is movably connected to the inside wall of the receptacle 502 by a hinge 513 or any other such means which allows the coupler 512 to be opened when pressure, for example, is forced against the coupler 512 as when the insert 501 is connected to the receptacle 502. An insert coupler opener 514 is also depicted extending parallel to the inside wall of receptacle 502 and a conduit 515 is depicted coupled to the receptacle 502.

The receptacle 502 also includes one or more seals 516 which extend from the inner wall of the receptacle 502. The seals may be made of any suitable material and are used to form a seal to minimize leakage or spillage of coolant during engagement, connection, and disengagement of the insert 501 with the receptacle 502 as depicted in FIGS. 5B and 5C. It will be appreciated that the seals 516 alternatively could be coupled to the exterior surface of insert 501 or a combination of both may be used.

In FIG. 5B, the quick connector 500 is depicted at a point during the engagement process of insert 501 with receptacle 502, but prior to the point where the insert coupler 504 and the receptacle coupler 512 have been engaged by insert coupler opener 514 and receptacle coupler opener 506, respectively. In FIG. 5B, insert 501 has been inserted into the receptacle 502 far enough to engage seals 516 thereby creating a seal preventing the leakage or spillage of coolant whenever the couplers are opened or partially opened.

In FIG. 5C, the quick connector 500 is depicted in the fully engaged stage. More specifically, couplers 504 and 512 are open and coolant is flowing from the insert 501 to the receptacle 502 as shown by the directional flow arrows or vice versa. Seals 516 are engaged with and remain engaged with insert 501. As the insert 501 is inserted further into the receptacle 502, receptacle opener 506 engages receptacle coupler 512 and forces it open. Similarly, insert coupler opener 514 engages insert coupler 504 and forces it open. When the insert 501 is fully inserted into the receptacle 502, the insert coupler and the receptacle coupler are fully opened, the insert engages a locking mechanism (not shown) for securing the connection. In FIG. 5C, the couplers are fully opened and the gate springs 503 and 511 are fully compressed.

It will be appreciated that FIG. 5B also depicts the disengagement process of insert 501 from receptacle 502 at a point when the insert coupler 504 and the receptacle coupler 512 have closed again and sealed. As the insert 501 is being removed from the receptacle 502, the force of insert gate spring 503 closes insert coupler 504 until it is fully closed. Similarly, the force of receptacle gate spring 511 closes receptacle coupler 512 until it is fully closed. The sealing activity of seals 516 with insert 501 is maintained until after both couplers 504 and 512 are fully closed and sealed.

Since it is virtually impossible to prevent completely some leakage or spillage of coolant, particularly when the insert is being disconnected from the receptacle any of the means for collecting the leakage or spillage described above may be used with the quick connector of FIG. 5 including, but not limited to, a trough or the coolant collector described in FIG. 4.

It will be appreciated that, when couplers 500 are used with the apparatus described in FIG. 3 above, for example, the resulting cooling system has the additional feature of establishing a seal between inserts and receptacles before any electrical connection of the circuit cards occurs and thereby protecting the electronics from inadvertent leaks or spills of coolant. Similarly, when the circuit cards are being disconnected, the seal between the inserts and the receptacles remains in place until after the electrical connection of the circuit card to the electronic system has been terminated, again protecting against spills or leaks while the circuit card is electrically coupled to the electronic system.

Thus, the present invention has been described herein with reference to particular embodiments for particular applications. Those having ordinary skill in the art and access to the present teachings will recognize additional modifications, applications, and embodiments within the scope thereof.

It is, therefore, intended by the appended claims to cover any and all such applications, modifications, and: embodiments within the scope of the present invention.

1. A cooling system for cooling heat-generating components in an electronic system comprising:
one or more heat exchange units having an inlet for receiving heated coolant and for cooling said coolant to provide cooled coolant at an outlet thereof;
one or more heat transfer units disposed on one or more boards or circuit cards and thermally coupled to one or more heat-generating components, the heat transfer units receiving cooled coolant at an inlet thereof from a heat exchange unit, transferring heat to the cooled coolant from one or more heat-generating components thermally coupled thereto and creating heated coolant and directing the heated coolant from an outlet thereof to a heat exchange unit for cooling the heated coolant;
an interconnect system for enabling and disabling coolant communication between the heat exchange units and the heat transfer units; and
a coolant transport system coupled to the inlets and outlets of heat transfer units and the heat exchange units and coupled to the interconnect system for transporting cooled coolant from the heat exchange units to the heat transfer units and for transporting heated coolant from the heat transfer units to the heat exchange units, the coolant transport system being disposed within the electronic system such that connection of the circuit cards to the electronic system engages the interconnect system enabling coolant communication between the heat transfer units disposed on such circuit card and one or more heat exchange units and disconnecting the circuit card from the electronic system disengages the interconnect system disabling coolant communication between the heat transfer units on such circuit card and the heat exchange units.

2. The cooling system as set forth in claim 1 wherein at least one heat exchange unit is disposed within the housing of the electronic system and coupled to the housing.

3. The cooling system as set forth in claim 1 wherein the interconnect system is comprised of one or more quick connectors having an insert and a receptacle and disposed such that one or more inserts and receptacles engage when a circuit card is connected to the electronic system enabling coolant communication and disconnect when a circuit card is disconnected from the electronic system, disabling coolant communication.

4. The cooling system as set forth in claim 3 wherein the quick connectors establish a seal before enabling or disabling coolant communication to minimize leakage of coolant when the quick connectors are being connected or disconnected, respectively.

5. The cooling system as set forth in claim 4 wherein the coolant transport system includes one or more heat transfer unit coolant transportation means disposed on one or more of the circuit cards and coupled to the inlets and outlets of the heat transfer units and coupled to one or more inserts or receptacles of the quick connectors such that such inserts or receptacles engage with their mating receptacles or inserts, respectively of the quick connectors when the circuit card is connected to the electronic system.

6. The cooling system as set forth in claim 5 wherein one or more of the inserts or receptacles of the quick connectors coupled to the heat transfer unit transportation means forms a seal when not engaged with its mating receptacle or insert, respectively, enabling such transportation means to contain coolant such that the cooling system has the appropriate volume of coolant at all times, irrespective of the number of circuit cards connected to the electronic system and minimizing the leakage or spillage of coolant from such transportation means.

7. The cooling system as set forth in claim 4 wherein the coolant transport system includes heat exchange unit coolant transportation means coupled to the inlets and outlets of one or more heat exchange units and coupled to one or more inserts or receptacles of the quick connector such that such inserts or receptacles engage with their mating receptacle or insert, respectively, of the quick connectors when a circuit card is connected to the electronic system.

8. The cooling system as set forth in claim 7 wherein one or more of the inserts or receptacles of the quick connectors coupled to the heat exchange unit transportation means forms a seal when not engaged with its mating receptacle or insert, respectively, thereby minimizing the leakage or spillage of coolant.

9. The cooling system as set forth in claim 1 wherein the transport system and interconnect system are disposed in the electronic system and on one or more of the circuits cards such that a secure mechanical connection of such circuit cards to the electronic system is maintained when the circuit cards are connected to the electronic system.

10. The cooling system as set forth in claim 1 further comprising:
collection means disposed in proximity to the interconnect system for collecting coolant spilled or leaked from the interconnect system and directing such spilled or leaked coolant back to the cooling system.

11. The cooling system as set forth in claim 10 further comprising:
sensing means disposed within the collection means for detecting the presence of coolant in the collection means and providing a notification to the electronic system user or operator there of.

12. The cooling system as set forth in claim 1 wherein the inlets of one or more heat transfer units are disposed below the outlets of such heat transfer units enhancing convective circulation of the coolant.

13. The cooling system as set forth in claim 1 wherein the inlets of one or more heat exchange units are disposed above the outlets of such heat exchange units enhancing convective circulation of the coolant.

14. The cooling system as set forth in claim 1 wherein the electronic system includes one or more slide guides for connecting and disconnecting the circuit cards from the electronic system.

15. A cooling system as set forth in claim 1 wherein one or more of the heat transfer units is a socket heat transfer unit, the socket heat transfer unit comprising:
a housing having one or more first cavities thermally coupled to one or more heat-generating components, wherein a coolant flowing through the cavities absorbs heat from the heat-generating components creating heated coolant;
means for electrically coupling electrical conductors of the heat-generating components to the electronic system;
one or more inlets for receiving coolant and directing the coolant through the cavities; and
one or more outlets for receiving heated coolant from the cavities and directing the heated coolant out of the socket heat transfer unit.

16. A data processing system having the cooling system of claim 1.

17. A device having one or more heat-generating components and having the cooling system of claim 1.

18. A method of cooling heat-generating components in an electronic system comprising the steps of.
receiving heated coolant at one or more heat exchange units and cooling such coolant to provide cooled coolant;
receiving cooled coolant at one or more heat transfer units, the heat transfer units being thermally coupled to one or more heat-generating components such that heat from the components is transferred to the coolant providing heated coolant;
transporting the heated coolant from the heat transfer units to the heat exchange units and transporting the cooled coolant from heat exchange units to the heat transfer units; and
enabling and disabling coolant communication between the heat exchange units and the heat transfer units when the heat-generating components are connected and disconnected, respectively, to or from the electronic system.

19. The method of claim 18 wherein one or more heat transfer units are disposed on one or more circuit cards and the enabling and disabling of coolant communication comprises connecting and disconnecting, respectively, the circuit cards to or from the electronic system.

20. A quick connector for establishing coolant communications in a cooling system for cooling heat-generating components in an electronic system comprising;
one or more inserts;
one or more receptacles for engaging with the inserts; and
first sealing means within the inserts and receptacles for sealing the inserts and connectors when such inserts and receptacles are not engaged and for unsealing the inserts and receptacles when such inserts and receptacles are engaged, thereby enabling coolant communication there through.

21. The quick connector as set forth in claim 20 further comprising:
second sealing means for creating a seal between an insert and receptacle prior to engagement of the insert with the receptacle and the unsealing of the first sealing means and the enabling of coolant communication and maintaining such seal between the insert and receptacle during disengagement of the insert from the receptacle until after the first sealing means has re-sealed, said second sealing means minimizing the coolant spilled or leaked during engagement and disengagement of the insert and the receptacle.

22. The quick connector of claim 20 further comprising:
a housing coupled to one or more receptacles and through which one or more of the inserts engages the one or more of the receptacles, the housing having means for collecting coolant spilled or leaked from the quick connector and for directing spilled or leaked coolant to a coolant source.

23. The quick connector as set forth in claim 22 having one or more sensors disposed in the housing for sensing the presence of coolant in the housing.

24. The quick connector as set forth in claim 23 having one or more detectors responsive to the sensors for providing an indication to the user or operator of the system of the presence of coolant in the housing.

25. The quick connector as set for in claim 22 wherein the means for collecting spilled or leaked coolant further includes means for forcing such spilled or leaked coolant to the coolant source.
